(19) United States
(12) Patent Application Publication
(10) Pub. No.: US 2023/0171372 A1
(43) Pub. Date: Jun. 1, 2023

(54) Method and Related Systems for Dynamically Overlaying an Image on an Object in a Streamed Video Sequence

(71) Applicant: Amine Arezki, Korntal (DE)

(72) Inventor: Amine Arezki, Korntal (DE)

(21) Appl. No.: 17/962,591

(22) Filed: Oct. 10, 2022

Related U.S. Application Data
(60) Provisional application No. 63/176,546, filed on Apr. 19, 2021.

(51) Int. Cl. H04N 5/265; G06T 5/50; G06T 7/70

(52) U.S. Cl. CPC H04N 5/265; G06T 5/50; G06T 7/70; G06V 2201/09; G06T 2207/20044; G06T 2207/20221; G06T 2207/30196

(57) ABSTRACT

A purpose of the invention is to provide a method and a system for adding or superimposing predetermined pictures, especially advertisement pictures, on predetermined location(s) of moving object(s), especially the clothing of sports players during a match, in a video stream. More generally, the invention aims at superimposing, in a video stream, at least one predetermined image portion at a predetermined location of at least one moving object image, to simulate that the object carries the predetermined image portion on. The disclosure also provides a system for implementing a bidding process to determine which symbols, logos, or messages are overlaid for various simultaneous broadcasts.

### FIELD OF INVENTION

The present invention relates to a method and a system for broadcasting images of moving objects, especially video images, with insertion of advertisement pictures or the like on specific locations of the moving objects.

### BACKGROUND

Systems for changing the content of advertisement pictures of broadcasted views are already known. For example, virtual reality systems superimpose adverts on predetermined static locations of a filmed area (for example, panels of a soccer or football stadium). Such systems are used, for advertising purposes, to modify the content of the advertisement depending on, for example, the country or the geographic area in which the images are broadcasted. The choice of the advertisement can be made in view of customer habits or legal aspects (for example, in some countries, tobacco or alcohol advertising is illegal). The limitation of such systems is that the advertisements are fixed to certain points or areas in the camera views.

It would be desirable to be able to superimpose pictures (especially advertisement) not only on static areas but also on moving objects, for example, on the clothing of players in broadcast games.

Not only would such a solution drastically increase the advertising space available to brands during sports matches and other types of broadcasts by dynamically making use of empty display space during said broadcasts, it would also allow for more targeted advertisements, since specific advertising content can be overlaid over a broadcast for a first target audience while different content can be simultaneously overlaid over the same original broadcast for other target audiences. Such a dynamic system would be beneficial not only for large brands but also for small businesses that wish to focus on a particular sub-group of a wider audience.

It is within this context that the present invention is provided.

### SUMMARY

A purpose of the invention is to provide a method and a system for adding or superimposing predetermined pictures, especially advertisement pictures, on predetermined location(s) of moving object(s), especially the clothing of sports players during a match, in a video stream. More generally, the invention aims at superimposing, in a video stream, at least one predetermined image portion at a predetermined location of at least one moving object image, to simulate that the object carries the predetermined image portion on. The disclosure also provides a system for implementing a bidding process to determine which symbols, logos, or messages are overlaid for various simultaneous broadcasts.

Thus, according to one aspect of the present disclosure there is provided a computer-implemented method of dynamically overlaying a preregistered image over a predetermined area of a moving object in a stream of video images, the method comprising the steps of: receiving, by a processor, a stream of video images of an object, including a first image of the object wherein the object is in an initial pose having an initial orientation and an initial position; analysing, by the processor, the first image to determine and extract a base structure of the object including the orientation of one or more surfaces and joints of the object; overlaying, by the processor, a preregistered image on the object at an orientation and position determined based on the extracted base structure.

Then, for each subsequent image, the method further involves, by the processor, estimating a change in position and orientation of the base structure and base structure joints, and adjusting the overlaid preregistered image in a corresponding manner to maintain its position and orientation with respect to the base structure.

In some embodiments, the moving object is a human. Furthermore, the base structure may be a virtual skeleton extracted based on the position of the human and wherein the preregistered image is overlaid over a particular position on a piece of clothing of the human.

In some embodiments, multiple preregistered images are overlaid at different relative positions of the object.

In some embodiments, the step of overlaying the preregistered image comprises a 2D to 3D coordinate transformation of the preregistered image based on the determined coordinates of the base structure.

In some embodiments, the preregistered image is selected from a plurality of received preregistered images based on a selection process.

In some embodiments, the method further comprises broadcasting the overlaid video images to multiple external devices.

The different preregistered images may be overlaid and simultaneously broadcasted to different external devices.

In some embodiments, the preregistered image is a static symbol, message, or logo.

Finally, in some embodiments, the preregistered image is an animated symbol, message, or logo.

According to a second aspect of the present disclosure, there is also provided a system platform for managing a plurality of dynamic advertisements for streamed content, the system comprising one or more processors configured to carry out a bidding process to determine a selection of symbols, messages, or logos received from various parties is to be overlaid over one or more broadcasts and once a determination is made, to carry out the method of any one of claims 1 to 10 with the one or more selected symbols, messages, or logos used as the preregistered image.

### BRIEF DESCRIPTION OF THE DRAWINGS

Various embodiments of the invention are disclosed in the following detailed description and accompanying drawings.

FIG. 1 illustrates an explanatory flow chart of the process of determining a base structure of an object, in this case a player, in an initial video image and overlaying first and second preregistered advertising images thereon for simultaneous broadcasts.

FIG. 2 illustrates a similar explanatory flow chart of the process of determining a base structure of a moving object, in this case a player moving between a first pose and a second pose, in a stream of video images and overlaying first and second preregistered advertising images thereon for simultaneous broadcasts.

FIG. 3 illustrates a flow chart of an example set of steps of the process of overlaying an image on an object in a video stream and the interaction with a corresponding process of determining a symbol, logo, or message to use as the preregistered image.

FIG. 4 illustrates an example system where a plurality of competing brands interact with a dynamic advertising management platform to determine which images are overlaid on the equipment of a sports team during a broadcast.

Common reference numerals are used throughout the figures and the detailed description to indicate like elements. One skilled in the art will readily recognize that the above figures are examples and that other architectures, modes of operation, orders of operation, and elements/functions can be provided and implemented without departing from the characteristics and features of the invention, as set forth in the claims.

### DETAILED DESCRIPTION AND PREFERRED EMBODIMENT

The following is a detailed description of exemplary embodiments to illustrate the principles of the invention. The embodiments are provided to illustrate aspects of the invention, but the invention is not limited to any embodiment. The scope of the invention encompasses numerous alternatives, modifications and equivalent; it is limited only by the claims.

Numerous specific details are set forth in the following description in order to provide a thorough understanding of the invention. However, the invention may be practiced according to the claims without some or all of these specific details. For the purpose of clarity, technical material that is known in the technical fields related to the invention has not been described in detail so that the invention is not unnecessarily obscured.

The present disclosure generally relates to methods and systems for superimposing images or messages, in particular advertising images or messages of one or more brands, on one or more positions of a moving object in a received video sequence, in particular the sports equipment of a player in the video sequence.

In the examples given, this augmented reality solution is based on determining a pose of a sports player and thus extracting a virtual skeleton to allow for easy transformation of the 2D coordinates of a preregistered image to the 3D coordinates of the player in the video sequence to overlay the advertising image or message on the player so that it moves and changes orientation with them so that it looks like it is at a fixed position on their sports equipment.

While the specific examples provided herein are all focused on this process of extracting a pose and virtual skeleton from a sports player in a video sequence, it will be understood that the general method could equally be applied to other objects in live video streams such as racing cars, for example.

Referring to FIG. 1, an explanatory flow chart is shown of the process of determining a base structure of an object, in this case a player, in an initial video image, and overlaying first and second preregistered advertising images thereon for simultaneous broadcasts.

The first and second preregistered images are advertising images that have been selected from a plurality of different brands according to a bidding selection process carried out by a dynamic ads digital platform as explained below.

The dynamic advertising platform receives images of a broadcast from a video source such as in the present example a live stream of a sports match containing video sequence of one or more players playing a game. The player's image 1, i.e. the object, is identified in the raw footage received by the platform.

Once the player's image 1 is identified and the preregistered images to be superimposed over the player are determined by the selection process, the advertising system analyses the received video sequence of the player to determine an initial pose of the player and based on the analysis creates a 3-dimensional virtual skeleton consisting of a plurality of virtual joints representing the player in the initial image for that pose.

The virtual skeleton has the major joints and structural lines of the object, i.e. player, allowing for quick estimations of the orientation and position of various surfaces covering the skeleton, i.e. patches of open space on the player's kit. Using such estimations, multiple advertising images determined earlier can be placed over various positions of the player's kit. In the present example, a large advertisement is placed over the player's torso, and two smaller advertisements are placed over their shoulder and thigh.

The images are then send to broadcasters for broadcast to viewing devices of the various viewers watching the match as with a regular broadcast. As such viewer populations often contain vastly different sections of audience in different territories, and as there are no limitations on parallel overlay operations as described above, different advertising images and messages can be overlaid on the player for different broadcasters, simultaneously. This is exemplified in FIG. 1 by AD 1 being overlaid on the torso of the player for broadcaster TV 1 and AD 2 being overlaid for broadcaster TV 2.

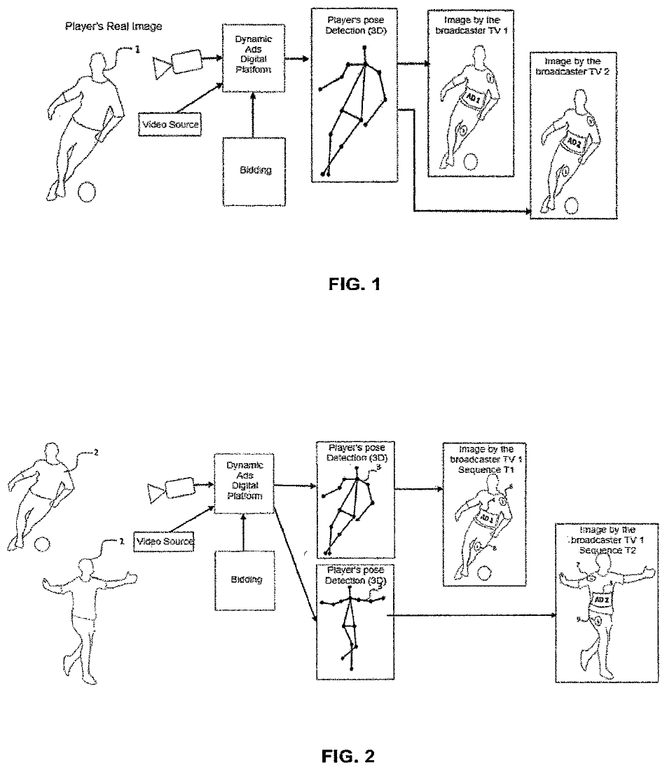

Referring to FIG. 2, a second explanatory flow chart is shown of the process of determining a base structure of a moving object, in this case a player moving between a first pose and a second pose, in a stream of video images, and overlaying first and second preregistered advertising images thereon for simultaneous broadcasts.

As can be seen in FIG. 2, the video source comprises different images of the same player including the image 2 of the player in an initial pose as described above and a second image 1 where the pose of the player has changed and thus the placement, i.e. sizing and orientation, of the overlaid advertising images must therefore be adjusted correspondingly.

A bidding process for determining which preregistered mages to overlay on the player is carried out by the dynamic advertising platform which receives the video data as with the process of FIG. 1.

The initial pose 2 of the player is then determined in the same manner by extracting the virtual skeleton 3. The virtual skeleton 3 can then be tracked in various subsequent images leading to a representation of the virtual skeleton in image 1.

The various preregistered advertising images are then overlaid for the different broadcasters as described above including a first large image 4 overlaid on the torso for broadcast 1, a second large image 5 overlaid on the torso for broadcast 2, a first small image 6 overlaid on the player shoulder in broadcast 1, a second small image 7 overlaid on the player shoulder in broadcast 2, a first small image 8 overlaid on the player thigh in broadcast 1, and finally a second small image 9 overlaid on the player thigh in broadcast 2. These are merely examples of positioning of the overlays and should not be interpreted as limiting.

The variation between messages and images overlaid would only be limited by the capabilities of the broadcasters receiving the overlaid images. For example, different messages might be shown on different teams. The differentiations between the teams could be done by detection of the jersey colour in order to superimpose the correct message (ADs) on the body. Different messages might also be shown on different players. The differentiation between players could be done by detection the player face or the jersey number.

The sports equipment on which the images are overlaid could be a T-shirt, shorts or any other sports accessory or even clothes of the technical staff of the club. They could also be overlaid on non-human objects such as cars as mentioned above.

The images superimposed over the objects could be messages, logos, or even animations and videos.

In terms of which images are overlaid over which objects for different broadcasts, a smart algorithm may be employed by the dynamic advertising system, or it may be determined by a bidding process.

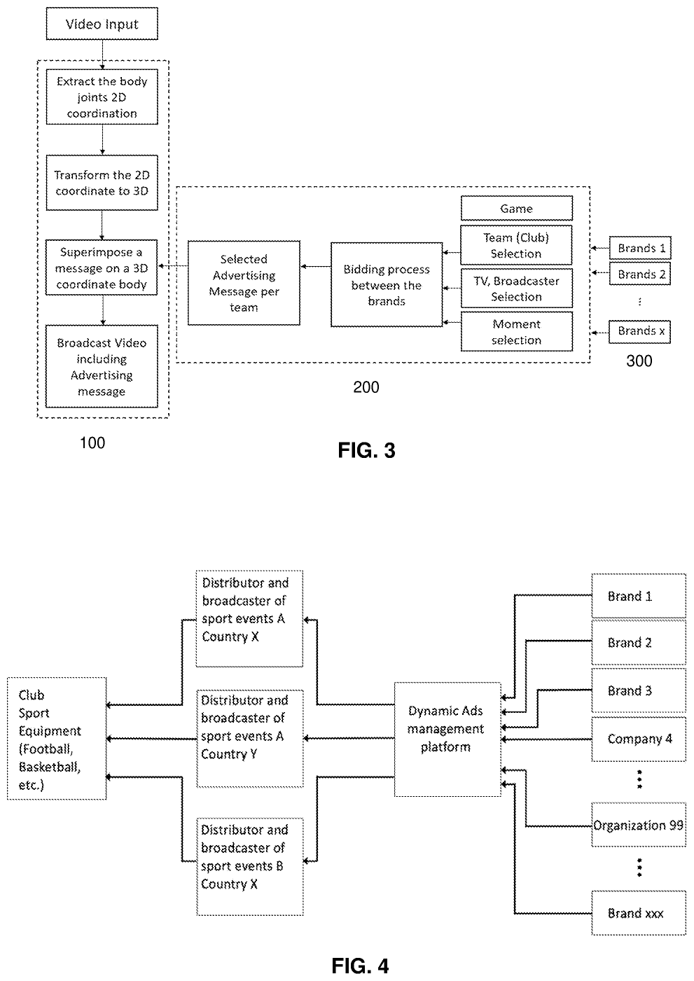

Referring to FIG. 3, a flow chart is shown of an example set of steps of the process of overlaying an image on an object in a video stream and the interaction with a corresponding process of determining a symbol, logo, or message to use as the preregistered image.

Each process may be managed by a separate software platform that interacts with the other.

In the present example, the video input is processed by a first advertisement mapping platform 100 and the determination of which advertising images should be overlaid in the video sequence is determined by a bidding selection platform 200. This is the basic structure of the overall dynamic advertising platform that manages both the selection process for the preregistered images to be overlaid on the objects in the video sequence and the process of overlaying itself.

As can be seen, various brands 300 compete for advertising slots on different games, teams, broadcasters, and time slots. The bidding management platform 200 then carries out a bidding process for each slot requested by one or more brands and forwards the images the winning brand wishes to display to the advertisement mapping platform 100 as a preregistered image for overlaying on the selected player/object in the selected game/time slot/broadcast.

Referring to FIG. 4, a more detailed flow chart representing an example configuration of the bidding management system of the platform is shown where a plurality of competing brands interact with each other on a dynamic advertising management platform to determine which images are overlaid on the equipment of a sports team during a broadcast.

The dynamic ad management platform will manage compatibility between brands and clubs, and intra-brands. The platform will offer the different possibilities in terms of television channel, particular moment and player and will also manage the broadcast priorities of the brands linked to the auction price.

The terminology used herein is for the purpose of describing particular embodiments only and is not intended to be limiting of the invention. As used herein, the term “and/or” includes any combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

It should be understood that the operations described herein may be carried out by any processor. In particular, the operations may be carried out by, but are not limited to, one or more computing environments used to implement the method such as a data center, a cloud computing environment, a dedicated hosting environment, and/or one or more other computing environments in which one or more assets used by the method re implemented; one or more computing systems or computing entities used to implement the method; one or more virtual assets used to implement the method; one or more supervisory or control systems, such as hypervisors, or other monitoring and management systems, used to monitor and control assets and/or components; one or more communications channels for sending and receiving data used to implement the method; one or more access control systems for limiting access to various components, such as firewalls and gateways; one or more traffic and/or routing systems used to direct, control, and/or buffer, data traffic to components, such as routers and switches; one or more communications endpoint proxy systems used to buffer, process, and/or direct data traffic, such as load balancers or buffers; one or more secure communication protocols and/or endpoints used to encrypt/decrypt data, such as Secure Sockets Layer (SSL) protocols, used to implement the method; one or more databases used to store data; one or more internal or external services used to implement the method; one or more backend systems, such as backend servers or other hardware used to process data and implement the method; one or more software systems used to implement the method; and/or any other assets/components in which the method is deployed, implemented, accessed, and run, e.g., operated, as discussed herein, and/or as known in the art at the time of filing, and/or as developed after the time of filing.

As used herein, the terms “computing system”, “computing device”, and “computing entity”, include, but are not limited to, a virtual asset; a server computing system; a workstation; a desktop computing system; a mobile computing system, including, but not limited to, smart phones, portable devices, and/or devices worn or carried by a user; a database system or storage cluster; a switching system; a router; any hardware system; any communications system; any form of proxy system; a gateway system; a firewall system; a load balancing system; or any device, subsystem, or mechanism that includes components that can execute all, or part, of any one of the processes and/or operations as described herein.

As used herein, the terms computing system and computing entity, can denote, but are not limited to, systems made up of multiple: virtual assets; server computing systems; workstations; desktop computing systems; mobile computing systems; database systems or storage clusters; switching systems; routers; hardware systems; communications systems; proxy systems; gateway systems; firewall systems; load balancing systems; or any devices that can be used to perform the processes and/or operations as described herein.

As used herein, the term “computing environment” includes, but is not limited to, a logical or physical grouping of connected or networked computing systems and/or virtual assets using the same infrastructure and systems such as, but not limited to, hardware systems, software systems, and networking/communications systems. Typically, computing environments are either known environments, e.g., “trusted” environments, or unknown, e.g., “untrusted” environments. Typically, trusted computing environments are those where the assets, infrastructure, communication and networking systems, and security systems associated with the computing systems and/or virtual assets making up the trusted computing environment, are either under the control of, or known to, a party.

Unless specifically stated otherwise, as would be apparent from the above discussion, it is appreciated that throughout the above description, discussions utilizing terms such as, but not limited to, “activating”, “accessing”, “adding”, “applying”, “analyzing”, “associating”, “calculating”, “capturing”, “classifying”, “comparing”, “creating”, “defining”, “detecting”, “determining” “eliminating”, “extracting”, “forwarding”, “generating”, “identifying”, “implementing”, “obtaining”, “processing”, “providing”, “receiving”, “sending”, “storing”, “transferring”, “transforming”, “transmitting”, “using”, etc., refer to the action and process of a computing system or similar electronic device that manipulates and operates on data represented as physical (electronic) quantities within the computing system memories, resisters, caches or other information storage, transmission or display devices.

Those of skill in the art will readily recognize that the algorithms and operations presented herein are not inherently related to any particular computing system, computer architecture, computer or industry standard, or any other specific apparatus. Various general purpose systems may also be used with programs in accordance with the teaching herein, or it may prove more convenient/efficient to construct more specialized apparatuses to perform the required operations described herein. The required structure for a variety of these systems will be apparent to those of skill in the art, along with equivalent variations. In addition, the present invention is not described with reference to any particular programming language and it is appreciated that a variety of programming languages may be used to implement the teachings of the present invention as described herein, and any references to a specific language or languages are provided for illustrative purposes only and for enablement of the contemplated best mode of the invention at the time of filing.

Unless otherwise defined, all terms (including technical terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

The disclosed embodiments are illustrative, not restrictive. While specific configurations of the method and system for overlaying a preregistered image on an object in a video sequence have been described in a specific manner referring to the illustrated embodiments, it is understood that the present invention can be applied to a wide variety of solutions which fit within the scope and spirit of the claims. There are many alternative ways of implementing the invention.

It is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A computer-implemented method of dynamically overlaying a preregistered image over a predetermined area of a moving object in a stream of video images, the method comprising the steps of:
receiving, by a processor, a stream of video images of an object, including a first image of the object wherein the object is in an initial pose having an initial orientation and an initial position;
analysing, by the processor, the first image to determine and extract a base structure of the object including the orientation of one or more surfaces and joints of the object;
overlaying, by the processor, a preregistered image on the object at an orientation and position determined based on the extracted base structure;
for each subsequent image, estimating a change in position and orientation of the base structure and base structure joints, and adjusting the overlaid preregistered image in a corresponding manner to maintain its position and orientation with respect to the base structure.

2. A computer-implemented method according to claim 1, wherein the moving object is a human.

3. A computer-implemented method according to claim 2, wherein the base structure is a virtual skeleton extracted based on the position of the human and wherein the preregistered image is overlaid over a particular position on a piece of clothing of the human.

4. A computer-Implemented method according to claim 1, wherein multiple preregistered images are overlaid at different relative positions of the object.

5. A computer-implemented method according to claim 1, wherein the step of overlaying the preregistered image comprises a 2D to 3D coordinate transformation of the preregistered image based on the determined coordinates of the base structure.

6. A computer-implemented method according to claim 1, wherein the preregistered image is selected from a plurality of received preregistered images based on a selection process.

7. A computer-implemented method according to claim 1, wherein the method further comprises broadcasting the overlaid video images to multiple external devices.

8. A computer-implemented method according to claim 7, wherein different preregistered images are overlaid and simultaneously broadcasted to different external devices.

9. A computer-implemented method according to claim 1, wherein the preregistered image is a static symbol, message, or logo.

10. A computer-implemented method according to claim 1, wherein the preregistered image is an animated symbol, message, or logo.

11. A system platform for managing a plurality of dynamic advertisements for streamed content, the system comprising one or more processors configured to carry out a bidding process to determine a selection of symbols, messages, or logos received from various parties is to be overlaid over one or more broadcasts and once a determination is made, to carry out the method of any one of claim 1 with the one or more selected symbols, messages, or logos used as the preregistered image.
